(19) United States
(12) Patent Application Publication
(10) Pub. No.: US 2024/0204738 A1
(43) Pub. Date: Jun. 20, 2024

(54) MULTI-MODE POWER AMPLIFYING APPARATUS

(71) Applicant: Skyworks Solutions, Inc., Irvine, CA (US)

(72) Inventors: Neal J. Tuffy, Great Shelford (GB); Tomas J. Tansley, Andover, MA (US); Valter Karavanic, Nashua, NH (US); Thierry Marie Favard, London (GB); Daniel James Pardi, Salem, NH (US)

(21) Appl. No.: 18/545,959

(22) Filed: Dec. 19, 2023

Related U.S. Application Data
(60) Provisional application No. 63/434,022, filed on Dec. 20, 2022.

(51) Int. Cl. H03F 3/24; H03F 1/56

(52) U.S. Cl. CPC H03F 3/245; H03F 1/56; H03F 2200/211; H03F 2200/451

(57) ABSTRACT

A multi-mode power amplifying apparatus has a power amplifier and an attenuator coupled to an input of the power amplifier. The power amplifying apparatus is adapted to operate in a plurality of operation modes and configured to amplify, in each operation mode, a radio frequency signal with an associated power amplifier gain. A tuning controller is configured to adjust a setting of the attenuator based on a current operation mode.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of this disclosure relate to multi-mode power amplifiers.

### Description of the Related Art

Many frequency communication systems can be used for transmitting or receiving signals in a wide range of frequencies. An RF communication system can be used for wireless communication using RF-signals in a frequency range to about 6 GHz.

RF communication systems include, but are not limited to, mobile phones, tablets, base stations, network access points, customer premises equipment (CPE), laptops and wearable electronics.

In certain applications, RF communication systems can transmit different signals in different operation modes. Radio frequency power amplifiers can be used in amplifying such RF signals for transmission.

### SUMMARY

In some aspects, the techniques described herein relate to a multi-mode power amplifying apparatus including: a power amplifier; an attenuator coupled to an input of the power amplifier; and a tuning controller, the multi-mode power amplifying apparatus adapted to operate in a plurality of operation modes and configured to amplify, in each operation mode of the plurality of operation modes, a radio frequency signal with an associated power amplifier gain, the tuning controller configured to adjust a setting of the attenuator based on a current operation mode of the plurality of operation modes.

In some aspects, the techniques described herein relate to a multi-mode power amplifying apparatus wherein the attenuator includes an attenuator bias circuit, and the tuning controller is configured to adjust the setting of the attenuator by controlling the attenuator bias circuit.

In some aspects, the techniques described herein relate to a multi-mode power amplifying apparatus wherein the setting corresponds to an attenuation profile over temperature.

In some aspects, the techniques described herein relate to a multi-mode power amplifying apparatus wherein the attenuator is coupled to the input of the power amplifier through an input matching network.

In some aspects, the techniques described herein relate to a multi-mode power amplifying apparatus wherein the power amplifier includes a gain stage, an interstage matching network, and an output stage, the gain stage coupled to the output stage via the interstage matching network, the tuning controller is further configured to adjust a setting of the interstage matching network based on the current operation mode.

In some aspects, the techniques described herein relate to a multi-mode power amplifying apparatus further including a feedback network coupled to an input of the power amplifier, the tuning controller configured to adjust a setting of the feedback network based on the current operation mode.

In some aspects, the techniques described herein relate to a multi-mode power amplifying apparatus wherein the power amplifier includes a gain stage and an output stage, and the feedback network is coupled between an output and an input of the gain stage, the tuning controller configured to control one or more switching elements of the feedback network based on the current operation mode.

In some aspects, the techniques described herein relate to a multi-mode power amplifying apparatus further including an output matching network coupled to an output of the power amplifier and having a first section and a second section, the power amplifier, the attenuator, and the first section residing on a first semiconductor die, the second section residing on a second semiconductor die, the tuning controller configured to adjust a setting of the first section and a setting of the second section based on the current operation mode.

In some aspects, the techniques described herein relate to a multi-mode power amplifying apparatus wherein the tuning controller is configured to adjust the setting of the first section by controlling one or more switching elements of the first section and to adjust the setting of the second section by controlling one or more switching elements of the second section.

In some aspects, the techniques described herein relate to a multi-mode power amplifying apparatus wherein the power amplifier includes a gain stage and a first bias circuit configured to bias the gain stage, the tuning controller configured to, based on the current operation mode, adjust a setting of the first bias circuit to set a base ballast of the gain stage.

In some aspects, the techniques described herein relate to a multi-mode power amplifying apparatus wherein the power amplifier further includes an output stage coupled to an output of the gain stage, and a and a second bias circuit configured to bias the output stage, the tuning controller configured to, based on the current operation mode, adjust a setting of the second bias circuit to set a base ballast of the output stage.

In some aspects, the techniques described herein relate to a multi-mode power amplifying apparatus including: a power amplifier including a first bias circuit configured to bias the power amplifier; and a tuning controller, the multi-mode power amplifying apparatus adapted to operate in a plurality of operation modes and configured to amplify, in each operation mode of the plurality of operation modes, a radio frequency signal with an associated power amplifier gain, the tuning controller configured to, based on a current operation mode of the plurality of operation modes, adjust a reference current profile over temperature for the first bias circuit.

In some aspects, the techniques described herein relate to a multi-mode power amplifying apparatus further including an attenuator, the tuning controller configured to adjust a setting of the attenuator based on the current operation mode.

In some aspects, the techniques described herein relate to a multi-mode power amplifying apparatus wherein the setting of the attenuator is an attenuator profile over temperature.

In some aspects, the techniques described herein relate to a multi-mode power amplifying apparatus wherein the power amplifier further includes a gain stage, an output stage, and a second bias circuit configured to bias the output stage, the first bias circuit configured to bias the gain stage, the tuning controller configured to, based on the current operation mode, adjust a reference current profile over temperature for the second bias circuit.

In some aspects, the techniques described herein relate to a multi-mode power amplifying apparatus further including a feedback network coupled to an input of the power amplifier, the tuning controller configured to control one or more switching elements of the feedback network based on the current operation mode.

In some aspects, the techniques described herein relate to a multi-mode power amplifying apparatus further including an output matching network coupled to an output of the power amplifier and having a first section and a second section, the power amplifier, the first bias circuit, and the first section residing on a first semiconductor die, the second section residing on a second semiconductor die, the tuning controller configured to adjust a setting of the first section and a setting of the second section based on the current operation mode.

In some aspects, the techniques described herein relate to a multi-mode power amplifying apparatus wherein the tuning controller is configured to adjust the setting of the first section by controlling one or more switching elements of the first section and to adjust the setting of the second section by controlling one or more switching elements of the second section.

In some aspects, the techniques described herein relate to a multi-mode power amplifying apparatus wherein the tuning controller is configured to, based on the current operation mode, adjust a setting of the first bias circuit to set a base ballast of the power amplifier.

In some aspects, the techniques described herein relate to a wireless communication device including a multi-mode power amplifying apparatus including power amplifier, an attenuator coupled to an input of the power amplifier, and a tuning controller, the multi-mode power amplifying apparatus adapted to operate in a plurality of operation modes and configured to amplify, in each operation mode of the plurality of operation modes, a radio frequency signal with an associated power amplifier gain, the tuning controller configured to adjust a setting of the attenuator based on a current operation mode of the plurality of operation modes; and an antenna coupled to an output of the multi-mode power amplifying apparatus.

In some aspects, the techniques described herein relate to a wireless communication device including: a power amplifying apparatus including a power amplifier, a first bias circuit configured to bias the power amplifier, and a tuning controller, the power amplifying apparatus adapted to operate in a plurality of operation modes and configured to amplify, in each operation mode of the plurality of operation modes, a radio frequency signal with an associated power amplifier gain, the tuning controller configured to, based on a current operation mode of the plurality of operation modes, adjust a reference current profile over temperature for the first bias circuit; and an antenna coupled to an output of the power amplifying apparatus.

In some aspects, the techniques described herein relate to a method of operating a multi-mode power amplifying apparatus, the method including: setting an attenuator of a power amplifying apparatus to a first state based on a first operation mode; amplifying a radio frequency signal with the power amplifying apparatus in the first operation mode; setting the attenuator of the power amplifying apparatus to a second state based on a second operation mode; and amplifying the radio frequency signal with the power amplifying apparatus in the second operation mode;

In some aspects, the techniques described herein relate to a method of operating a multi-mode power amplifying apparatus, the method including: setting a reference current profile over temperature for a first bias circuit of a power amplifying apparatus to a first state based on a first operation mode; amplifying a radio frequency signal with the power amplifying apparatus in the first operation mode; setting the reference current profile over temperature for the first bias circuit to a second state based on a second operation mode; and amplifying the radio frequency signal with the power amplifying apparatus in the second operation mode.

In some aspects, the techniques described herein relate to a multi-mode power amplifying apparatus including: a power amplifier adapted to operate in different operation modes and configured to amplify in each operation mode a radio frequency, RF, signal with an associated power amplifier gain; and a tuning controller adapted to tune the power amplifier gain of the power amplifier in each operation mode independently.

In some aspects, the techniques described herein relate to a multi-mode power amplifying apparatus wherein the power amplifier includes at least two stages.

In some aspects, the techniques described herein relate to a multi-mode power amplifying apparatus wherein each stage of the power amplifier includes at least one main power amplification transistor and at least one auxiliary power amplification transistor.

In some aspects, the techniques described herein relate to a multi-mode power amplifying apparatus wherein the power amplifier includes a gain stage and an output stage.

In some aspects, the techniques described herein relate to a multi-mode power amplifying apparatus wherein the gain stage includes an RF signal input adapted to receive a radio frequency, RF, signal from an attenuator of the power amplifier amplifying apparatus through an input matching network and an RF signal output adapted to output a radio frequency, RF, signal amplified by the gain stage through an interstage matching network to an RF input of the output stage.

In some aspects, the techniques described herein relate to a multi-mode power amplifying apparatus wherein an RF signal output of the gain stage is fed back to an RF signal input of the gain stage through a feedback network.

In some aspects, the techniques described herein relate to a multi-mode power amplifying apparatus wherein the tuning controller is adapted to control switching elements of a feedback network provided between an RF signal output of a gain stage of the power amplifier and an RF signal input of the gain stage of the power amplifier to tune the power amplifier gain of the power amplifier.

In some aspects, the techniques described herein relate to a multi-mode power amplifying apparatus wherein each stage of the power amplifier includes an associated stage bias circuit.

In some aspects, the techniques described herein relate to a multi-mode power amplifying apparatus wherein the stage bias circuit of a stage of said power amplifier includes a main bias circuitry adapted to provide a bias current for main power amplification transistors of the associated stage and auxiliary bias circuitry adapted to provide a bias current for auxiliary power amplification transistors of the associated stage.

In some aspects, the techniques described herein relate to a multi-mode power amplifying apparatus wherein the tuning controller is adapted to control the main bias circuitry and the auxiliary bias circuitry of each stage bias circuit to tune the power amplifier gain of the power amplifier.

In some aspects, the techniques described herein relate to a multi-mode power amplifying apparatus wherein the attenuator of the amplifying apparatus includes an associated attenuator bias circuit adapted to supply the attenuator with a bias current.

In some aspects, the techniques described herein relate to a multi-mode power amplifying apparatus wherein the tuning circuit is adapted to control the attenuator bias circuit of the attenuator of the power amplifying apparatus to tune the power amplifier gain of the power amplifier.

In some aspects, the techniques described herein relate to a multi-mode power amplifying apparatus wherein the output stage of the power amplifier includes an RF output adapted to output an RF signal amplified by said output stage to an output matching network.

In some aspects, the techniques described herein relate to a multi-mode power amplifying apparatus wherein the output matching network includes a mode selection switch adapted to switch the multi-mode power amplifying apparatus between main operation modes.

In some aspects, the techniques described herein relate to a multi-mode power amplifying apparatus wherein the tuning circuit is adapted to control switching elements of the output matching network connected to the RF output of the output stage of said power amplifier.

In some aspects, the techniques described herein relate to a multi-mode power amplifying apparatus wherein the tuning circuit is adapted to control switching elements of the interstage matching network to tune the power amplifier gain of the power amplifier.

In some aspects, the techniques described herein relate to a multi-mode power amplifying apparatus wherein the operation modes of the multi-mode power amplifying apparatus includes at least one of a wireless local area mode and a wireless personal area mode.

In some aspects, the techniques described herein relate to a multi-mode power amplifying apparatus wherein the wireless local area mode includes a WiFi mode.

In some aspects, the techniques described herein relate to a multi-mode power amplifying apparatus wherein the WiFi mode includes a High Power WiFi mode, a Mid Power WiFi mode, and a Low Power WiFi mode.

In some aspects, the techniques described herein relate to a multi-mode power amplifying apparatus wherein the personal area mode includes a Bluetooth mode.

In some aspects, the techniques described herein relate to a multi-mode power amplifying apparatus wherein the Bluetooth mode includes a High Power Bluetooth mode, a Mid Power Bluetooth mode and a Low Power Bluetooth mode.

In some aspects, the techniques described herein relate to a wireless communication device including a multi-mode power amplifying apparatus including a power amplifier adapted to operate in different operation modes and configured to amplify in each operation mode a radio frequency, RF, signal with an associated power amplifier gain and including a tuning controller adapted to tune the gain of said power amplifier in each operation mode independently; an output matching network; and an antenna operatively coupled to the multi-mode power amplifying apparatus via the output matching network.

In some aspects, the techniques described herein relate to a method for amplifying a radio frequency, RF, signal by a multi-mode power amplifying apparatus, the method including: selecting an operation mode of the multi-mode power amplifying apparatus; tuning a gain of the power amplifying apparatus for the selected operation mode of the power amplifying apparatus; and amplifying the RF signal with the tuned power amplifier gain.

### BRIEF DESCRIPTION OF THE DRAWINGS

Embodiments of this disclosure will now be described, by way of non-limiting example, with reference to the accompanying drawings.

FIG. 1 is a schematic circuit diagram of an exemplary multi-mode power amplifying apparatus according to some embodiments of the present invention;

FIG. 2 is a table illustrating the operation of the multi-mode power amplifying apparatus of FIG. 1 in different operation modes under control of a tuning controller;

FIG. 3 is a circuit diagram for illustrating a possible implementation of a gain stage within the multi-mode power amplifying apparatus as illustrated in FIG. 1;

FIGS. 4 to 9 are diagrams for illustrating simulation results by different performance parameters of a multi-mode power amplifying apparatus according to some embodiments of the present invention;

FIG. 10 is a flowchart for illustrating an exemplary method for amplifying a radio frequency, RF, signal according to some embodiments of the present invention;

FIG. 11 is a block diagram for illustrating a mobile device which includes a multi-mode power amplifying apparatus according to some embodiments of the present invention;

FIG. 12 is a schematic diagram of a power amplifier system including a multi-mode power amplifying apparatus according to some embodiments of the present invention.

FIG. 13 is a schematic diagram of a power amplifier system including a multi-mode power amplifying apparatus according to some embodiments of the present invention.

### DETAILED DESCRIPTION

The following description of certain embodiments presents various description of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Demands for a reduced power amplifier (PA) footprint coupled with improved RF performance can introduce significant challenges for frontend module (FEM) suppliers, particularly to maintain high levels of power amplifier performance with reduced FEM size. Wireless local area network (WLAN) and Bluetooth standards share overlapping frequency bands at 2.45 GHz but have different power and linearity requirements. There is a demand for an increasing number of operation modes in both wireless and Bluetooth operation to support performance optimization over different output power levels. The provision of more operation modes does enable a power amplifier to achieve compliance to the FCC's ever evolving and stringent linearity requirements, whilst minimizing power consumption, for a greater number of discrete output powers.

Moreover, to minimize the die size of the power amplifier, a single chain RF power amplifier solution can be preferable. However, a single-chain radio frequency, RF, power amplifier solution can present performance challenges as compared to a dedicated radio frequency, RF, power amplifier chain for each operation mode. For a number N of operation modes, an optimum performance can be obtained from a corresponding number of independent power amplifier chains. Accordingly, there is a challenge to execute a best trade-off in performance for all footprint operation modes from a single radio frequency, RF, chain to approach a performance that could be obtained from a number N of independent radio frequency, RF, power amplifier chains.

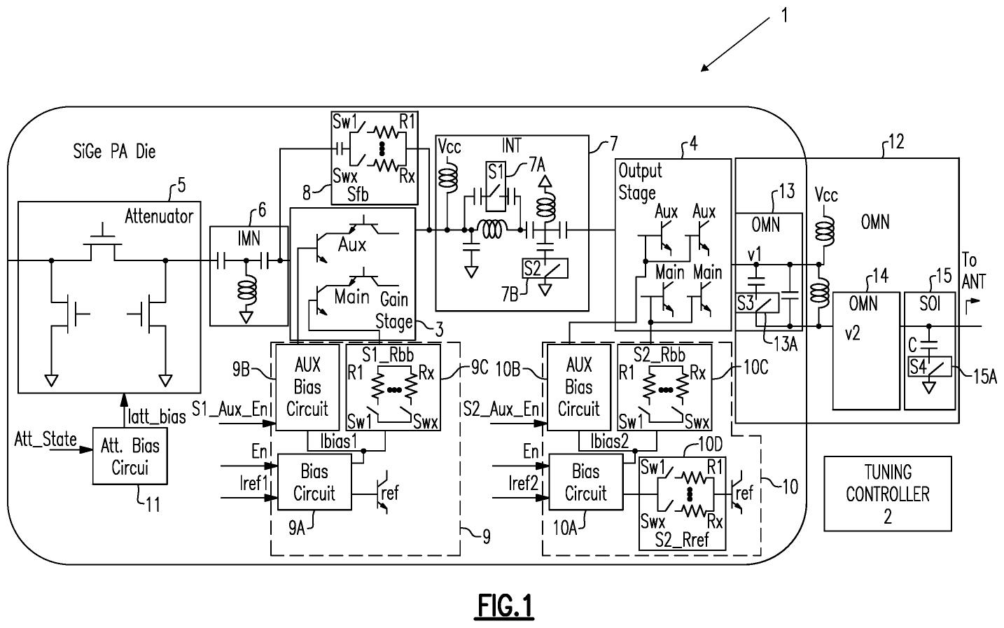

FIG. 1 shows an exemplary embodiment of a multi-mode power amplifying apparatus 1 according to a first aspect of the present invention. The multi-mode power amplifying apparatus 1 comprises a power amplifier adapted to operate in different operation modes and is configured to amplify in each operation mode a radio frequency, RF, signal with an associated power amplifier gain G. The illustrated multi-mode power amplifying apparatus 1 comprises a tuning controller 2 adapted to tune the power amplifier gain G of the power amplifier in each operation mode independently. To achieve performance equivalence between a single-chain power amplifier using a number N of Bluetooth or WLAN (WiFi) modes, and a number N of dedicated and independent WLAN or Bluetooth radio frequency power amplifier chains, the multi-mode power amplifying apparatus 1 according to the first aspect of the present invention uses a digital tuning controller 2 and registers to optimize various reconfiguration handles in different operation modes.

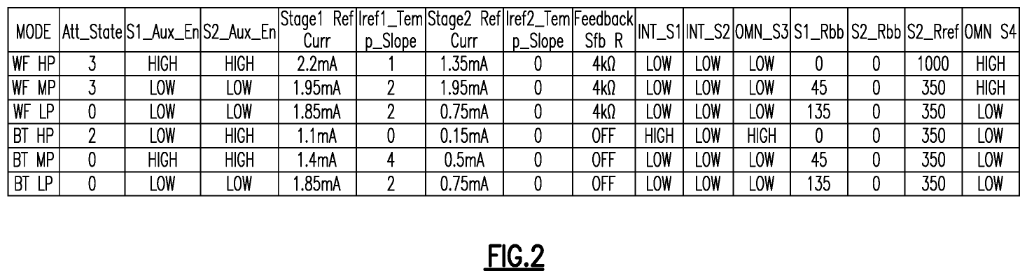

The power amplifier comprises at least two stages. In the illustrated exemplary embodiment, the multi-mode power amplifying apparatus 1 comprises a gain stage 3 and an output stage 4. Each stage of the multi-mode power amplifying apparatus 1 comprises in the illustrated embodiment at least one main power amplification transistor (Main) and at least one auxiliary power amplification transistor (Aux). The gain stage 3 of the multi-mode power amplifying apparatus 1 comprises an RF-signal input adapted to receive a radio frequency, RF, signal from an attenuator 5 of the power amplifying apparatus through an input matching network 6. The gain stage 3 further comprises an RF-signal output adapted to output a radio frequency, RF, signal amplified by the gain stage 3 through an interstage matching network 7 to an RF-input of the output stage 4. The RF-signal output of the gain stage 3 is fedback to an RF-signal input of the gain stage 3 through a feedback network 8. The tuning controller 2 is adapted to control switching elements SW of the feedback network 8 provided between the RF-signal output of the gain stage 3 of the power amplifier and the RF-signal input of the gain stage 3 of the power amplifier to tune the power amplifier gain G. FIG. 2 illustrates values of various control parameters for six different operating modes including three WiFi modes and three Bluetooth modes. For example, the tuning controller 2 can be adapted to control the various components including the switches SW1 to SWx within the switchable feedback network 8 and the other components according to the current operational mode.

In the illustrated embodiment of FIG. 1, the multi-mode power amplifying apparatus 1 comprises two stages, i.e., a gain stage 3 and an output stage 4. In the illustrated embodiment, each stage of the power amplifier comprises an associated stage bias circuit. In the illustrated implementation of FIG. 1, the gain stage 3 comprises an associated gain stage bias circuit 9. Further, the output stage 4 comprises an associated output stage bias circuit 10. Each stage bias circuit of a stage of the power amplifier comprises a main bias circuitry 9A and an auxiliary bias circuitry 9B as also illustrated in FIG. 1.

In the illustrated embodiment of FIG. 1, the main stage bias circuit 9 comprises a main bias circuitry 9A and an auxiliary bias circuitry 9B. The main bias circuitry 9A is adapted to provide a bias current for main power amplification transistors (Main) of the associated gain stage 3. The auxiliary bias circuitry 9B is adapted to provide a bias current for auxiliary power amplification transistors (Aux) of the associated gain stage 3.

The output stage bias circuit 10 associated with the output stage 4 also comprises a main bias circuitry 10A and an auxiliary bias circuitry 10B. The main bias circuitry 10A is adapted to provide a bias current for main power amplification transistors (Main) within the associated output stage 4. The auxiliary bias circuitry 10B is adapted to provide a bias current for auxiliary power amplification transistors (Aux) of the associated output stage 4.

In the illustrated embodiment of FIG. 1, the tuning controller 2 is adapted to control the main bias circuitry and the auxiliary bias circuitry of each stage bias circuit 9, 10 to tune the power amplifier gain G of the power amplifier. In the illustrated implementation of FIG. 1, the tuning controller 2 is adapted to control switching elements SW within an RF tuning circuit 9C of the main stage bias circuit 9. Further, the tuning controller 2 is adapted to control switching elements SW of an RF tuning circuit 10C of the output stage bias circuit 10. In a possible implementation, the tuning controller 2 is further adapted to control also switches of a further RF tuning circuit 10D of the output stage bias circuit 10 as illustrated in FIG. 1.

The feedback network 8 and each RF tuning circuit 9C, 10C, 10D can include a number x of parallel paths. Each Path can have a switching element SW and a resistor R connected in series to the switching element SW being controlled by the tuning controller 2. The switching elements SW can be implemented by controllable semiconductor elements, in particular by bipolar transistors or by MOSFETs.

In the illustrated embodiment of FIG. 1, the attenuator 5 of the power amplifying apparatus comprises an associated attenuator bias circuit 11 adapted to supply the attenuator 5 with a bias current. The tuning controller 2 is adapted to control the attenuator bias circuit 11 of the attenuator 5 to tune the power amplifier gain G of the power amplifier according to the operation mode.

The output stage 4 of the power amplifier comprises an RF-output adapted to output a radio frequency, RF, signal amplified by the output stage 4 to an output matching network 12. The output matching network 12 comprises a mode selection switch 15A adapted to switch the multi-mode power amplifying apparatus 1 between main operation modes. The tuning controller 2 is adapted to control switching elements of the output matching network 12 connected to the RF-output of the output stage 4 of the power amplifier.

In a possible embodiment, the tuning controller 2 is further adapted to control switching elements of the interstage matching network 7 to tune the power amplifier gain G of the power amplifier. In the illustrated implementation of FIG. 1, the interstage matching network 7 comprises a first switching element 7A and a second switching element 7B which are both controlled by the tuning controller 2 (e.g., via the settings “INT_S1” and “INT_S2” of FIG. 2, respectively).

The output matching network 12 can comprise in a possible implementation a first output matching network circuitry 13 connected to a second output matching network circuitry 14 being connected to a semiconductor-on-insulator die 15 of the output network 12. A split output matching network architecture can be implemented that incorporates load line switching via a switch capacitor C connected to the switch 15A. The switch 15A and the capacitor C can be on a silicon-on-insulator (SOI) die 15 as illustrated in FIG. 1. The switching can introduce an output matching network loss that may degrade performance. In certain applications, a single switch at the load end of the output matching network 12 together with a surface mounted technology (SMT) series inductor can allow a relatively large range of WiFi load line control around a Smith chart with a relatively minor impact on the real part of the Bluetooth load line impedance. The switching capacitor C being at or near an antenna port can allow an impedance trajectory that moves from a highly inductive Bluetooth load line toward a real but lower load line in a WiFi operation mode of the multi-mode power amplifying apparatus 1 according to the present invention as illustrated in the embodiment of FIG. 1. The Bluetooth load line impedance can be tuned or set with the first output matching network circuitry 13 and with the second output matching network circuitry 14, 15 used to tune or set the WiFi mode load line impedance.

In a possible embodiment, the multi-mode power amplifying apparatus 1 as shown in FIG. 1 comprises at least one wireless local area mode (WLAN) and at least one wireless personal area mode (WPAN). The wireless local area mode can comprise a WiFi mode (WF). The personal area mode comprises in a possible implementation a Bluetooth (BT) mode. The possible WiFi modes of the multi-mode power amplifying apparatus 1 can comprise in a possible implementation a high power (HP) WiFi mode, a mid Power (MP) WiFi mode and a low Power (LP) WiFi mode. Similarly, the Bluetooth operation modes may comprise in a possible implementation an HP BT mode, an MP BT mode and an LP BT mode.

In a possible embodiment, the multi-mode power amplifying apparatus 1 includes six operation modes including three WiFi (WF) modes and three BT modes. FIG. 2 shows a table for illustrating the operation of the multi-mode power amplifying apparatus 1 as illustrated in the circuit diagram of FIG. 1 with six operation modes including three WiFi modes WF-HP, WF-MP, WF-LP and three BT modes including operation modes BT-HP, BT-MP and BT-LP.

The tuning controller 2 is adapted to tune or adjust an amplifier power gain G for each of the six operation modes independently using different handles as illustrated in the embodiment of FIG. 1. The tuning controller 2 can influence the attenuation bias current supplied to the attenuator 5 by the attenuation bias circuit 11 by applying an attenuation state (“Att_state”) to the attenuation bias circuit 11. For example, the tuning controller 2 can set the attenuator 5 to one of a plurality of states that each correspond to a different attenuation-over-temperature profile. The tuning controller 2 can further enable the auxiliary bias circuit 9B by means of a first enable control signal S1_Aux_En and the auxiliary bias circuit 10B by means of a second enable control signal S2_Aux_En.

For instance, in the first operation mode WF-HP (WiFi High Power mode), both auxiliary bias circuits 9B, 10B are enabled (S1_Aux_En=high; S2_Aux_En=high). The tuning controller 2 can further control the switch elements SW within the feedback network 8 (feedback Sfb R). Further, the tuning controller 2 is adapted to control both switches 7A, 7B within the interstage matching network 7 (INTS1; INTS2).

In a possible implementation, the tuning controller 2 further can control the switch 13A within the output matching network circuitry 13 (OMN_S3) and the switch 15A in the circuitry 15 (OMN_S4). Further, the tuning controller 2 can control in a possible implementation switching elements SW within the tuning circuitry 9C and the tuning circuitry 10C of the stage bias circuits 9, 10. U.S. Patent Application Publication Nos. 2023/0370026, 2023/0370027, and 2023/0396220, each filed on May 9, 2023, describe configurable multi-mode power amplifier apparatuses and methods compatible with certain embodiments described herein. For example, the multi-mode power amplifiers shown in FIGS. 1A-1B, 2A, and 3-7 of each of the foregoing applications, and described in the corresponding text, are hereby incorporated by reference herein and can be compatible with certain embodiments described herein. The entirety of the disclosures of the foregoing applications are additionally incorporated by reference herein.

Accordingly, the multi-mode power amplifying apparatus 1 may comprise a plurality of handles including a switchable stage feedback, an input attenuator adjustment control and bypass feature and switchable stages of the stage bias circuitry to tune the power amplifier gain G in the respective operation mode. Further, RF switches 7A, 7B within the interstage matching network 7 as well as switches in the output matching network 12 are provided to allow the tuning controller 2 to tune the power amplifier gain G of the power amplifier in each operation mode independently. The provision of the different handles enables a finer gain control for different gain requirements in each operation mode. Usually, the switchable active attenuator's attenuation over temperature (as set by the attenuator state) and a switchable stage reference current profile over temperature allow to tune the power amplifier gain G over temperature for the different operation modes. Further, any stability concerns due to excessive gain can be easily addressed by altering the register settings for a particular operation mode.

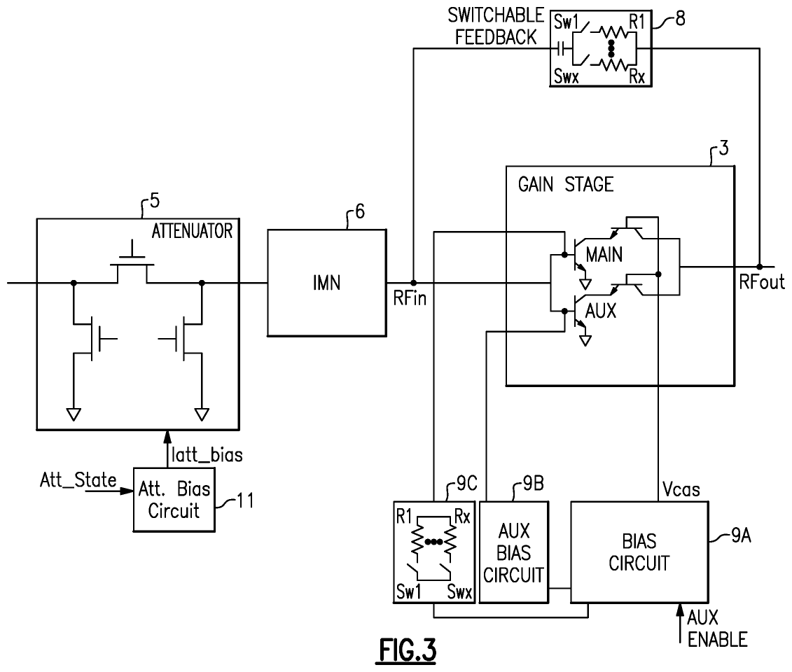

FIG. 3 illustrates a possible implementation of the gain stage 3 within the multi-mode power amplifying apparatus 1 as also illustrated in FIG. 1. The gain stage 3 comprises an associated stage bias circuit 9 including a main bias circuitry 9A and an auxiliary bias circuitry 9B. The gain stage 3 comprises at least one main power amplification transistor (Main) and at least one auxiliary power amplification transistor (Aux) as shown in FIG. 3. The main bias circuitry 9A is adapted to provide a bias current for the main power amplification transistors of the gain stage 3. The auxiliary bias circuitry 9B is adapted to provide a bias current for the auxiliary power amplification transistors of the gain stage 3. The tuning controller 2 is adapted to control the main bias circuitry 9A and the auxiliary bias circuitry 9B of the gain stage 3 to tune the power amplifier gain G of the power amplifier individually for each operation mode.

In a possible embodiment, the tuning controller 2 supplies an auxiliary enable signal (e.g., determined by the “S1_Aux_En” setting from FIG. 2) to the bias circuitry 9A to control if half, or all of the power transistors within the gain stage 3 are on. The tuning controller 2 can also supply a temperature profile control signal (e.g., determined by the “Iref1_Temp_Slope” setting in FIG. 2) to the bias circuitry 9A, which determines a temperature profile of the reference current Iref1, and supply a temperature profile control signal (e.g., determined by the “Iref2_Temp_Slope” setting in FIG. 2) to the bias circuitry 10A, which determines a temperature profile of the reference current Iref2. Further, the tuning controller 2 can control the switches within the circuitry 9C (e.g., determined by the setting “S1_Rbb” from FIG. 2). These switches control a ballast resistance to tune the RF gain versus power of the gain stage 3. The tuning controller 2 can also control the switches within the circuitry 10C (e.g., determined by the setting “S2_Rbb” from FIG. 2). These switches control a ballast resistance to tune the RF gain versus power of the output stage 3. Further, the tuning controller 2 can apply an attenuation state digital input signal (e.g., “Att_State” from FIG. 2) which drives the attenuation bias circuit 11 to provide an attenuation bias circuit which biases the field effect transistors of the attenuator 5 depending on a gain requirement in each operation mode. A combination of the active attenuator state of the attenuator 5 (e.g., determined by the setting “Att_State” of FIG. 2), a feedback resistance selection through the feedback network 8 (e.g., determined by the setting “Feedback Sfb R” of FIG. 2), a reference current temperature profile (e.g., determined by setting “Iref1_Temp_Slope” and/or “Iref2_Temp_Slope”) and auxiliary device Enable control signals (e.g., determined by the settings “S1_Aux_En” and/or “S2_Aux_En”) allows for control over overall power amplifier gain G over temperature and the output power from the gain stage 3 in each operation mode independently.

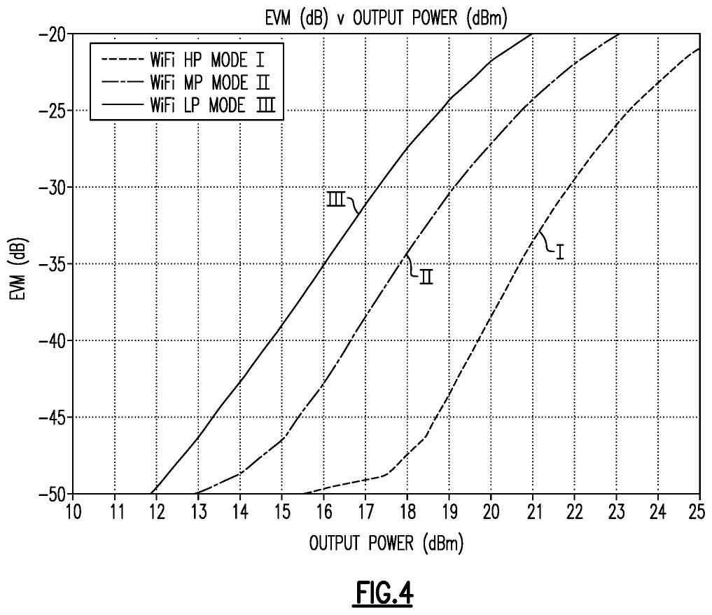

FIGS. 4 to 9 illustrate simulation results for different WiFi operation modes of the multi-mode power amplifying apparatus 1.

FIG. 4 illustrates the error vector magnitude (EVM) versus output power for different WiFi modes.

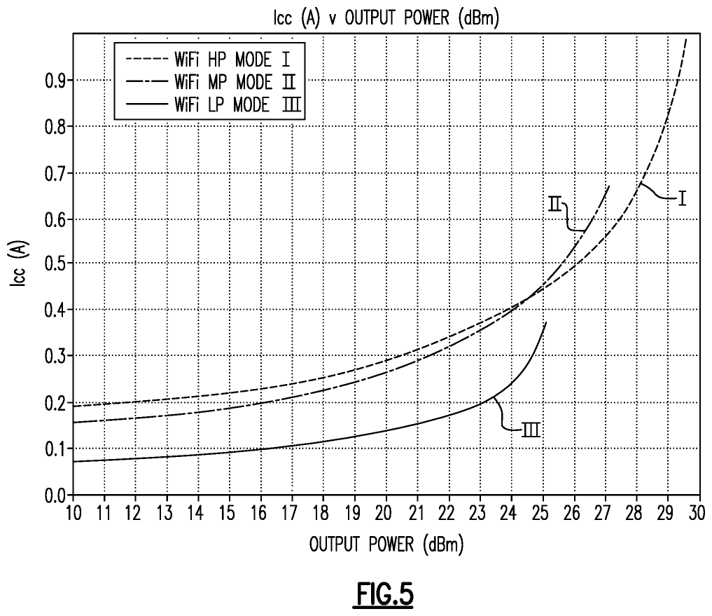

FIG. 5 illustrates the ICC current versus output power for three different WiFi operation modes.

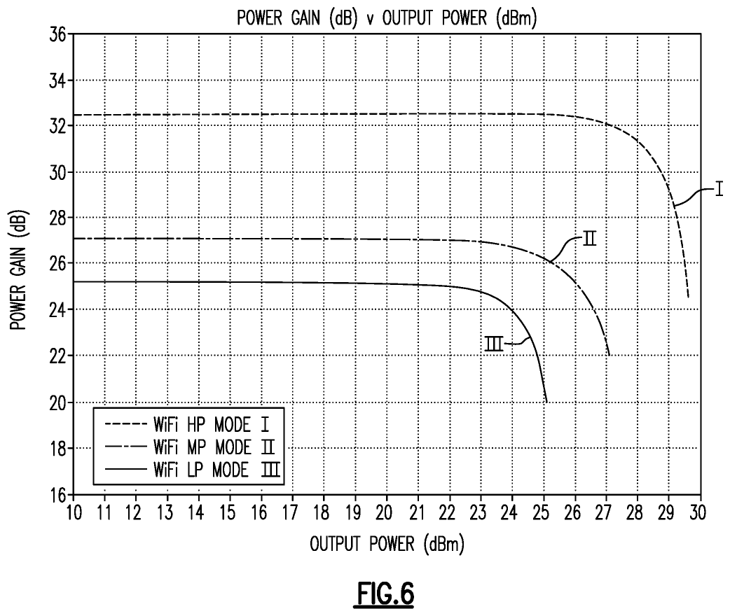

FIG. 6 illustrates the power gain G versus output power for the three different WiFi operation modes.

As can be seen from FIGS. 4, 5, 6, the multi-mode power amplifying apparatus 1 according to the present invention delivers an optimized EVM when switching between different WiFi operation modes. Further, the power gain G is also optimized for each WiFi operation mode as can be seen from FIG. 6. The proposed handles also allow for simultaneous ICC minimization of the different WiFi operation modes as can be seen from FIG. 5.

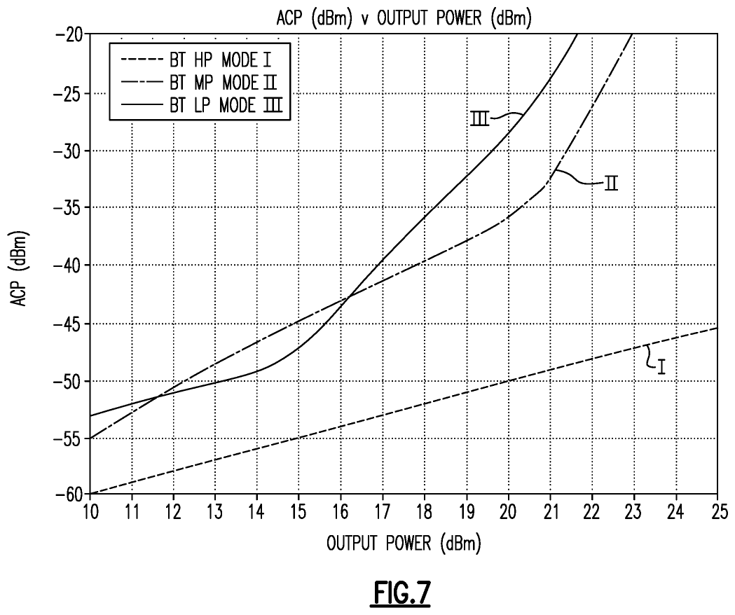

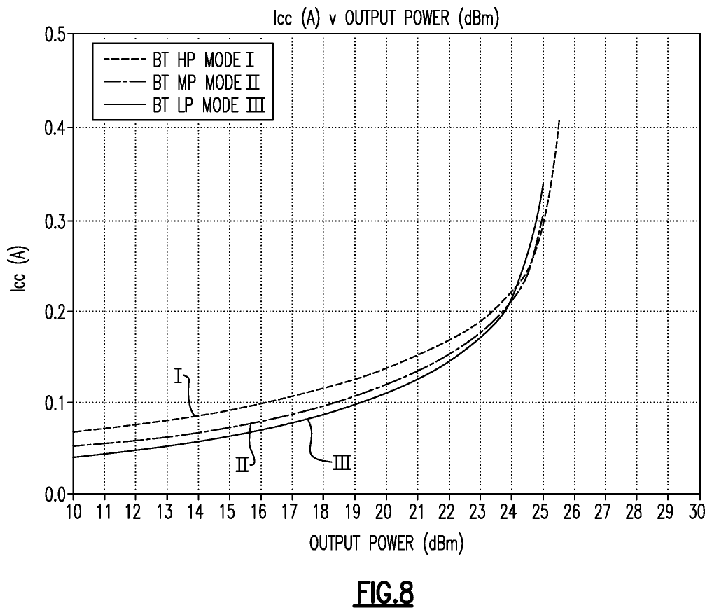

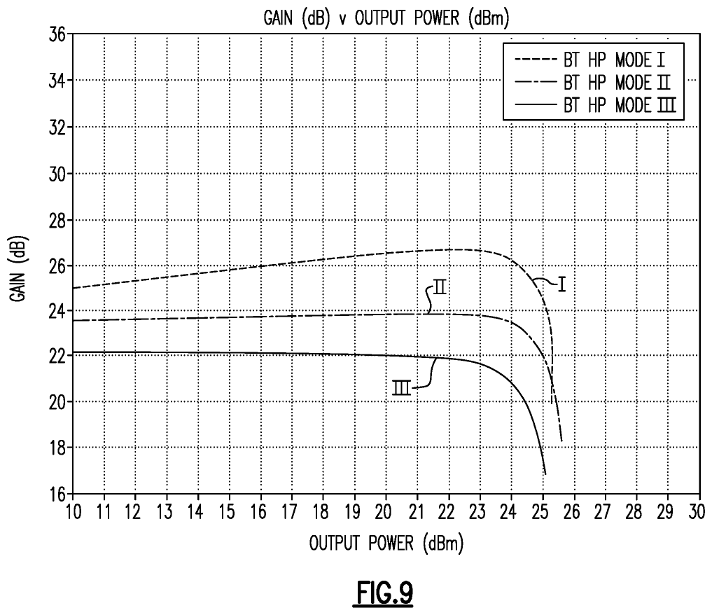

FIGS. 7, 8, and 9 illustrate simulation results for BT operation modes. As can be seen from FIG. 7, the multi-mode power amplifier operation delivers an optimized adjacent channel power (ACP) when switching between the three different BT operation modes. Further, the gain G and ICC-current are simultaneously optimized for each BT operation mode using the tuning handles of the tuning controller 2 as can be seen from FIGS. 8 and 9.

The multi-mode power amplifying apparatus 1 provides a good performance in each operation mode as illustrated in FIGS. 4 to 9. To achieve the performance as illustrated in the simulation results of FIGS. 4 to 9, the tuning controller 2 can tune the different control elements according to the table illustrated in FIG. 2. The performance benefits include reduced power consumption across the different operation modes and an improved linearity. The linearity and ICC trade-off that is encountered in each operation mode can be optimized using the control elements of the tuning controller 2. The power gain G can be mostly tailored and independently controlled by a gain control scheme as discussed in context with FIG. 3. Stability concerns can also be mitigated in a possible implementation by fine control of the gain of the gain stage 3 in each operation mode. With the implementation of the multi-mode power amplifying apparatus 1 according to the present invention as illustrated in the circuit diagrams of FIGS. 2 and 3, a die size reduction of the power amplifier can be achieved as well.

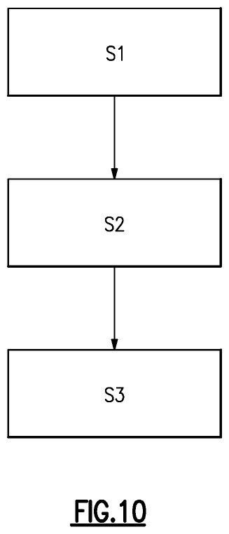

FIG. 10 shows a flowchart of a possible exemplary embodiment of a method for amplifying a radio frequency, RF, signal by a multi-mode power amplifying apparatus 1 such as the multi-mode power amplifying apparatus illustrated in the exemplary embodiment of FIG. 2.

In the illustrated embodiment of FIG. 10, the method may comprise three main steps.

In a first step S1, an operation mode OP-MODE of the multi-mode power amplifying apparatus 1 is selected.

In a further step S2, a gain G of the multi-mode power amplifying apparatus 1 is tuned for the selected operation mode OP-MODE of the power amplifying apparatus.

In a further step S3, the radio frequency, RF, signal is amplified with the tuned power amplifier gain G.

In a possible implementation, a tuning and/or retuning can be performed periodically or in response to an observed event, in particular a retuning command received by the tuning controller 2 from an external control unit via a control interface of the multi-mode power amplifying apparatus 1. The table illustrated in FIG. 2 can be stored in a possible embodiment in a configuration memory of the tuning controller 2. The number of operation modes OP-MODE can vary depending on the use case. In a possible implementation, the tuning controller 2 can also comprise a configuration memory which stores several different settings or tables as illustrated in FIG. 2 for a plurality of different operation modes depending on the use case.

In a possible embodiment, the tuning controller 2 receives a mode selection signal OP-MODE-SEL from an external control unit to set one of the six operation modes illustrated in the table of FIG. 2. In response to the received operation mode selection signal, a specific operation mode is set and a gain G of the power amplifying apparatus 1 is tuned by the tuning controller 2 for the selected operation mode using the different handles as illustrated in the circuit diagram of FIG. 1. After having tuned the gain G for the selected operation mode, the radio frequency, RF, signal received by the power amplifying apparatus 1 from a radio frequency, RF, signal source is amplified with the tuned power amplifier gain G.

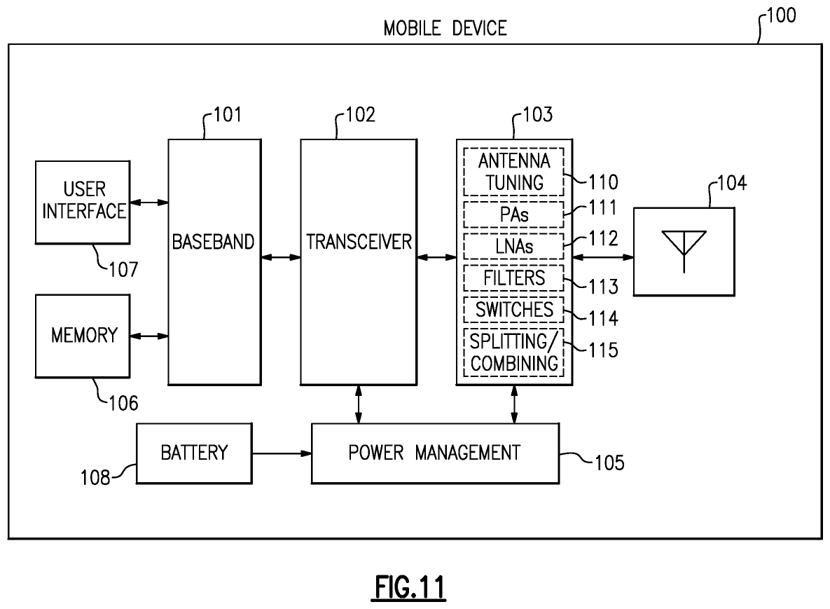

FIG. 11 illustrates a schematic diagram of a possible embodiment of a mobile device 100. The mobile device 100 can include one or more multi-mode power amplifying apparatus 1 according to the first aspect of the present invention. The mobile device 100 includes in the illustrated embodiment of FIG. 11 a baseband system 101, a transceiver 102, a frontend system 103, antennas 104, a power management system 105, a memory 106, a user interface 107 and a battery 108. The mobile device 100 can be used for communication using a wide variety of communication technologies. These communication technologies include, but are not limited to, 2G, 3G, 4G (including LTE, LTE-Advanced and LTE-Advanced Pro), 5G NR, WLAN (for instance WiFi), WPAN (for instance Bluetooth or Zigbee), WMAN (for instance WiMax) and/or GPS technologies.

The transceiver 102 generates in the illustrated embodiments RF-signals for transmission. Further, the transceiver 102 can process incoming RF-signals received from the antennas 104 of the mobile device 100. It will be understood that various functionalities associated with the transmission and receiving of radio frequency, RF, signals can be achieved by one or more components that are collectively represented in FIG. 11 as the transceiver 102. In a possible exemplary embodiment, separate components, for instance separate circuits or dies, can be provided for handling certain types of RF-signals.

The frontend system 103 is adapted to condition signals transmitted to and/or received from the antennas 104. In the illustrated exemplary embodiment of FIG. 11, the frontend system 103 includes an antenna tuning circuitry 110, power amplifiers 111, low noise amplifiers 112, filters 113, switches 114 and signal-splitting/combining circuitry 115. Any suitable principles and advantages of the multi-mode power amplifying apparatus 1 can be implemented in the power amplifiers 111 as shown in the schematic diagram of FIG. 11. The power amplifiers 111 can include the multi-mode power amplifying apparatus 1 with different WiFi and Bluetooth operation modes.

The frontend system 103 shown in the block diagram of FIG. 11 can provide a number of functionalities including, but not limited to, amplifying signals for transmission, amplifying receive signals, filtering signals, switching between different frequency bands, switching between different power modes, switching between transmission and receiving modes, duplexing of signals, multiplexing of signals or some combination thereof.

The antennas 104 of the mobile device 100 illustrated in the block diagram of FIG. 11 can include antennas used for a wide variety of types of communications. For example, the antennas 104 may include antennas for transmitting and/or receiving signals associated with a wide variety of frequencies and communication standards.

In a possible implementation, the antennas 104 may support MIMO communications and/or switched diversity communications. For example, MIMO communications use multiple antennas for communicating multiple data streams over a single radio frequency channel. MIMO communications benefit from higher signal-to-noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 100 illustrated in the block diagram of FIG. 11 can operate as beamforming in certain implementations. For example, the frontend system 103 can include amplifiers having a controllable gain and phase shifters having a controllable phase to provide beam formation and directivity from transmission and/or reception of signals using the antennas 104. For example, in the context of signal transmission, the amplitude and phases of the transmit signals provided by the antennas 104 can be controlled such that radiated signals from the antennas 104 combine using constructive and destructive interference to generate an aggregate transmit signal exhibiting beam-like qualities with more signal strength propagating in a particular direction. In the context of signal reception, the amplitude and phases are controlled such that more signal energy is received when the signal is arriving to the antennas 104 from a particular direction. In certain implementations, the antennas 104 include one or more arrays of antenna elements to enhance beamforming.

In the illustrated embodiment of FIG. 11, the baseband system 101 is coupled to the user interface 107 to facilitate processing of various user input and output (I/O) such as voice and data. The baseband system 101 provides the transceiver 102 of the mobile device 100 with digital representations of transmit signals, which the transceiver 102 processes to generate RF-signals for transmission. The baseband system 101 also processes digital representations of receive signals provided by the transceiver 102. As shown in FIG. 11, the baseband system 101 is coupled to the memory 106 to facilitate operation of the mobile device 100.

The memory 106 of the mobile device 100 can be used for a wide variety of purposes, such as storing data and/or instructions to facilitate the operation of the mobile device 100 and/or to provide storage of user information.

The power management system 105 of the mobile device 100 as illustrated in FIG. 11 provides a number of power management functions of the mobile device 100. In certain implementations, the power management system 105 includes a power amplifier supply control circuit that controls the supply voltages of the power amplifiers 111 which can comprise a multi-mode power amplifying apparatus 1 according to the first aspect of the present invention. For example, the power management system 105 can be configured to change the supply voltages provided to one or more of the power amplifiers 111 to improve efficiency such as power added efficiency (PAE).

As can be seen from FIG. 11, the power management system 105 receives a battery voltage from the battery 108. The battery 108 can comprise any suitable battery for use in a mobile device 100, including, for example a lithium-ion battery.

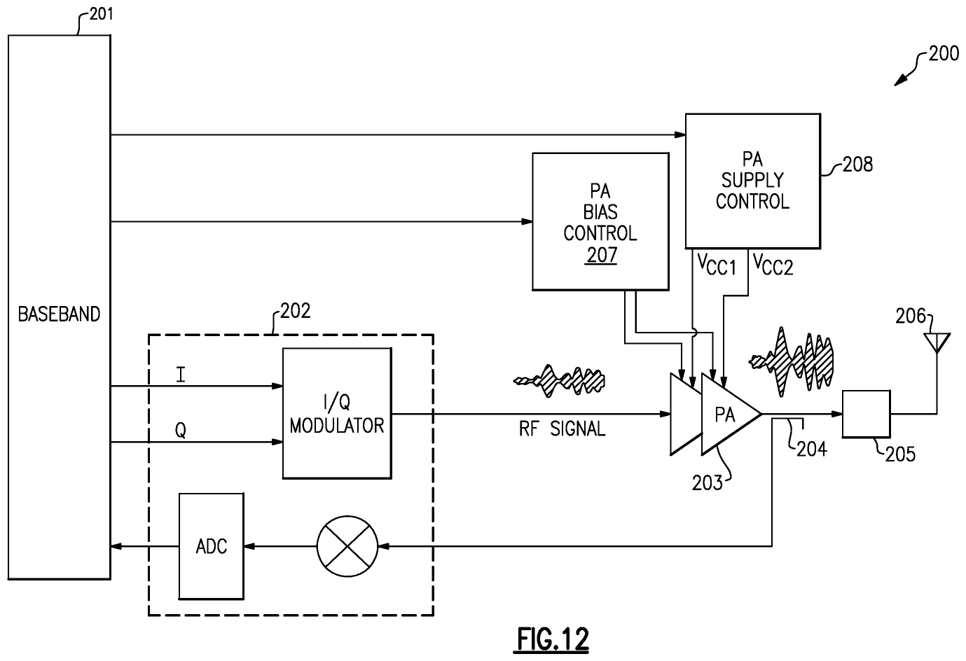

FIG. 12 is a schematic diagram for illustrating a power amplifier system 200 which may include one or more multi-mode power amplifying apparatuses 1 according to some embodiments of the present invention. The power amplifier system 200 can be part of the mobile device 100 of FIG. 11. The power amplifier system 200 can have multiple operation modes in accordance with any suitable principles and advantages disclosed herein.

The illustrated power amplifier system 200 includes in the illustrated embodiment a baseband processor 201, a transmitter/observation receiver 202, a power amplifier 203, a directional coupler 204, a frontend circuitry 205, an antenna 206, a power amplifier bias control circuitry 207 and a power amplifier supply control circuit 208. The power amplifier 203 can implement any suitable principles and advantages of the multi-mode power amplifying apparatus 1 according to the first aspect of the present invention. The power amplifier bias control circuit 207 can provide one or more mode control signals and/or one or more reference currents applied to the power amplifier 203 in accordance with any suitable principles and advantages disclosed herein. The illustrated transmitter/observation receiver 202 includes in the illustrated implementation an IQ modulator, a mixer and an analog-to-digital converter (ADC). In certain implementations, the transmitter/observation receiver 202 can be integrated into a transceiver.

The baseband processor 201 can be used to generate an in-phase (I) signal and a quadrature phase (Q) signal which can be used to represent a sinusoidal wave or signal of a desired amplitude, frequency and phase. For example, the I-signal can use to represent an in-phase component of the sinusoidal wave and the Q-signal can be used to represent a quadrature phase component of the sinusoidal wave, which can be an equivalent representation of the sinusoidal wave. In certain implementations, the I- and Q-signals can be provided to the IQ modulator of the transmitter/observation receiver 202 in a digital format. The baseband processor 201 can comprise any suitable processor configured to process a baseband signal. For instance, the baseband processor 201 can include a digital signal processor (DSP), a microprocessor, a programmable core, or any combination thereof. Moreover, in some implementations, two or more baseband processors 201 can be included in the power amplifier system 200 illustrated in FIG. 12.

The IQ modulator of the transmitter/observation receiver 202 can be configured to receive the I/Q-signals from the baseband processor 201 and can process the received I/Q-signals to generate an RF-signal. For example, the IQ modulator can include digital-to-analog converters (DACs) configured to convert the I/Q-signals into an analog format or mixes for up-converting the I/Q-signals to the radio frequency, RF, signal and a signal combining the up-converted I/Q-signals into an RF-signal suitable for amplification by the power amplifiers 203 shown in FIG. 12. In certain implementations, the IQ modulator can include one or more filters configured to filter a frequency content of signals processed therein.

The power amplifiers 203 which can comprise a multi-mode power amplifying apparatus 1 according to the first aspect of the present invention can receive the RF signal from the IQ modulator, and when enabled, can provide an amplified RF-signal to the antenna 206 via the frontend circuitry 205. The RF-signal received from the IQ modulator as the RF-signal source is amplified by the multi-mode power amplifying apparatus 1 within the power amplifier 203 according to the set operation mode and the power amplifier gain G tuned by the tuning controller 2 of the multi-mode power amplifying apparatus 1.

The frontend circuitry 205 can be implemented in a wide variety of ways. In possible embodiments, the frontend circuitry 205 includes one or more switches, filters, duplexers, multiplexers and/or other components. In a further possible embodiment, the frontend circuitry 205 can be omitted in favor so that the power amplifier 203 can provide the amplified RF-signal directly to the antenna 206.

The directional coupler 204 can sense an output signal of the power amplifier 203. Additionally, the sensed output signal from the directional coupler 204 can be provided to a mixer of the transmitter/observation receiver 202. The mixer is adapted to multiply the sensed output signal by a reference signal of a controlled frequency. The mixer operates to generate a downshifted signal by downshifting the sensed output signal's frequency content. The downshifted signal can be provided to the analog-digital-converter ADC of the transmitter/observation receiver 202. The analog-to-digital converter ADC can convert the downshifted signal to a digital format suitable for processing by the baseband processor 201. Including a feedback path from the output of the power amplifier 203 to the baseband processor 201 can provide several advantages. For example, implementing the baseband processor 201 in this manner can aid in providing power control, compensating for transmitter impairments and/or in performing digital pre-distortion (DPD). Although only one example of a sensing path of a power amplifier is illustrated in FIG. 12, other implementations are possible.

The power amplifier supply control circuit 208 is adapted to receive a power control signal from the baseband processor 201. The power amplifier supply control circuit 208 can control supply voltages of the power amplifier 203 including the multi-mode power amplifying apparatus 1 according to the first aspect of the present invention. In the illustrated configuration of FIG. 12, the power amplifier supply control circuit 208 can generate a first supply voltage VCC1 for powering an input stage of the power amplifier 203 and a second supply voltage VCC2 for powering an output stage of the power amplifier 203. The power amplifier supply control circuit 208 can further control the voltage level of the first supply voltage VCC1 and/or the second supply voltage VCC2 to enhance the power amplifier system's power-added efficiency (PAE).

The power amplifier supply control circuit 208 can employ various power management techniques to change the voltage level of one or more of the supply voltages over time to improve the power amplifier's PAE, thereby reducing power dissipation.

A possible technique used for improving efficiency of the power amplifier is average power tracking (APT). In average power tracking, a DC/DC converter can be used to generate a supply voltage for a power amplifier based on the power amplifier's average output power. Another possible technique for improving efficiency of a power amplifier comprises envelope tracking (ET), in which a supply voltage of the power amplifier is controlled in relation to the envelope of the RF signal. Thus, when a voltage level of the envelope of the RF signal increases, the voltage level of the power amplifier's supply voltage can also be increased. Likewise, when the voltage level of the envelope of the RF signal increases, the voltage level of the power amplifier's supply voltage can be decreased to reduce power consumption.

In certain configurations, the power amplifier supply control circuit 208 comprises a multi-mode supply control circuit that can operate in multiple supply modes including an APT mode and/or an ET mode. For example, the power control signal from the baseband processor 201 can instruct the power amplifier supply control circuit 208 to operate in a particular supply control mode.

As illustrated in the embodiment of FIG. 12, the power amplifier bias control circuit 207 can receive a bias control signal from the baseband processor 201 which generates bias control signals for the power amplifier 203 which can comprise a multi-mode power amplifying apparatus 1 according to the first aspect of the present invention. In the illustrated configuration, the bias control circuit 207 is adapted to generate bias control signals for both an input stage of the power amplifier 203 and an output stage of the power amplifier 203. However, other implementations are possible as well.

Any of the embodiments described above can be implemented in association with mobile devices such as cellular handsets. Some of the embodiments described above have provided examples in connection with mobile devices such as the mobile device 100 illustrated in FIG. 11. However, the principles and advantages of the embodiments can be used for any other systems or apparatus that have need for power amplifier systems. An example for such RF communication systems and apparatus include, but are not limited to, uplink wireless communication devices, mobile phones, tablets, base stations, network access points, customer premises equipment (CPE), laptops, and also wearable electronics.

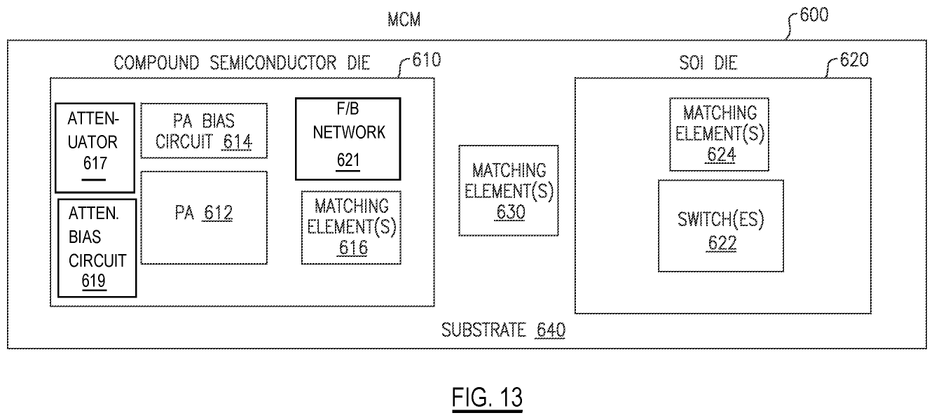

FIG. 13 illustrates an example a multi-chip module 600. The multi-chip module 600 includes a compound semiconductor die 610, a SOI die 620, and matching element(s) 630 on a substrate 640. The compound semiconductor die 610 includes a power amplifier 612 (e.g., the power amplifier of the apparatus 1 of FIG. 1), a bias circuit 614 (e.g., one or more of the bias circuits 9, 19 of the apparatus 1 of FIG. 1), and one or more matching elements 616. The power amplifier 612 and the bias circuit 614 can be implemented in accordance with any suitable principles and advantages of the multi-mode power amplifier systems disclosed herein. The compound semiconductor die 610 can be a SiGe die. The one or more matching elements 616 can be included in one or more of an input matching network (e.g., the input matching network 6 of the apparatus 1 of FIG. 1), an interstage matching network (e.g., the interstage matching network 7 of the apparatus 1 of FIG. 1), and a first section an OMN of a multi-mode power amplifier system (e.g., the first section 13 of the OMN 12 of the apparatus 1 of FIG. 1). The semiconductor die 610 can also include an attenuator 617 and an attenuator bias circuit 619 (e.g., the attenuator 5 and the attenuator bias circuit 11 of the apparatus 1 of FIG. 1). In addition, the semiconductor die 610 can include a feedback network 621 (e.g., the feedback network 8 of the apparatus 1 of FIG. 1).

The matching element(s) 630 can include one or more SMT capacitors, one or more SMT inductors, one or more trace inductors, one or more wire bond inductors, or any suitable combination thereof. For example, the matching elements 630 can include matching elements of the OMN section 14 of the apparatus 1 of FIG. 1. The first section of the OMN can include at least one of the matching element(s) 630 on the substrate 640. A second section of the OMN can include at least one of the matching element(s) 630 on the substrate 640. For example, the matching element(s) 630 can include a series SMT inductor of the second section of the OMN. The substrate 640 can be a laminate substrate.

The SOI die 620 can include switch(es) 622 and matching element(s) 624. SOI switches can provide relatively high isolation, relatively low loss, one or more other desirable technical features for switches, or any suitable combination thereof. The switch(es) 622 can include a switch of the second section of the OMN (e.g., a switch of the section 15 of the OMN 12 of the apparatus 1 of FIG. 1) to adjust output matching impedance for the power amplifier 612. The switch(es) 622 can include one or more switches in a PA signal path, such as one or more band select switches, one or more transmit/receive switches, one or more antenna switches, or any suitable combination thereof. The matching element(s) 624 can include one or more capacitors and/or one or more inductors implemented on the SOI die 620 (e.g., a capacitor of the section 15 of the OMN 12 of the apparatus 1 of FIG. 1). The matching element(s) 624 can include one or more passive impedance elements of the second section of the OMN. For example, the matching element(s) 624 can include a shunt capacitor connected to a switch of the switch(es) 622 that can be implemented in accordance with any suitable principles and advantages of the multi-mode power amplifier systems disclosed herein. The matching element(s) 624 can include one or more passive impedance elements of the first section of the OMN. While not shown in FIG. 13, the multi-chip module 600 can also include a tuning controller (e.g., the tuning controller 2 of the apparatus 1 of FIG. 1), which can be implemented in an integrated circuit mounted to the substrate 640, for example.

Aspects of this disclosure can be implemented in various electronic devices. Examples of such electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smartphone, a wearable computing device such as a smartwatch or an ear piece, a handheld computer, a laptop computer, a tablet computer, a home appliance, a vehicle or electronic system such as an automotive electronic system, a robot such as an industrial robot, or an Internet of Things device, etc. Further, an electronic device can also include unfinished products.

Any of the principles and advantages discussed herein can be implemented in association with RF circuits configured to amplify and process signals having a frequency in a range from about 30 kHz to 300 GHz, such as in a frequency range from 400 MHz to 8.5 GHz. Such radio frequency, RF, signals can include wireless local area network signals and/or wireless personal area network signals. The power amplifier systems disclosed herein can generate RF-signals at frequencies with frequency range 1 (FR1), fifth generation (5G) New Radio (NR) specification.

Unless the context requires otherwise, throughout the description and the claims, the words comprise, comprising, include, including and the like are to be construed in an inclusive sense, as opposed to an exclusive or exhaustive sense; that is to say, in the sense of including but not limited to. Moreover, conditional language used herein such as among others, may, could, might, can, for example such as and the like unless specifically stated otherwise, is otherwise understood within the context as used, is generally intended to convey that certain embodiments include, and other embodiments do not include, certain features, elements and/or states. The word “coupled” as generally used herein refers to two or more elements that may be either directly connected, or connected by way of one or more intermediate elements. Likewise, the word connected as generally used herein refers to two or more elements that may be either directly connected, or connected by way of one or more intermediate elements. Additionally, the words herein, above, below and words of similar import, when used in this application, shall refer to this application as a whole and not to any particular portions of this application. If the context permits, words in the above detailed description using the singular or plural number may also include the plural or singular number, respectively. The word or in reference to a list of two or more items, said word covers all of the following interpretations of the word: any of the items in the list, all of the items in the list, and any combination of the items in the list.

The above detailed description is not intended to be exhaustive or to limit the embodiments of the disclosure to the precise form disclosed above. While specific embodiments and examples are described above for illustrative purposes, various equivalent modifications are possible within the scope of the disclosure, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined and/or modified. Each of these processes or blocks may be implemented in a variety of different ways. Also, while processes or blocks are at times shown as being performed in series, these processes or blocks may instead be performed in parallel, or may be performed at different times.

The teachings provided herein can be applied to other systems, not necessarily the system described above. The elements and acts of the various embodiments described above can be combined to provide further embodiments.

While certain embodiments have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and the equivalents are intended to cover such forms or modifications as would fall within the scope and spirit of the disclosure.

What is claimed is:

1. A multi-mode power amplifying apparatus comprising:
a power amplifier;
an attenuator coupled to an input of the power amplifier; and
a tuning controller, the multi-mode power amplifying apparatus adapted to operate in a plurality of operation modes and configured to amplify, in each operation mode of the plurality of operation modes, a radio frequency signal with an associated power amplifier gain, the tuning controller configured to adjust a setting of the attenuator based on a current operation mode of the plurality of operation modes.

2. The multi-mode power amplifying apparatus of claim 1 wherein the attenuator includes an attenuator bias circuit, and the tuning controller is configured to adjust the setting of the attenuator by controlling the attenuator bias circuit.

3. The multi-mode power amplifying apparatus of claim 2 wherein the setting corresponds to an attenuation profile over temperature.

4. The multi-mode power amplifying apparatus of claim 1 wherein the attenuator is coupled to the input of the power amplifier through an input matching network.

5. The multi-mode power amplifying apparatus of claim 1 wherein the power amplifier includes a gain stage, an interstage matching network, and an output stage, the gain stage coupled to the output stage via the interstage matching network, the tuning controller is further configured to adjust a setting of the interstage matching network based on the current operation mode.

6. The multi-mode power amplifying apparatus of claim 1 further comprising a feedback network coupled to an input of the power amplifier, the tuning controller configured to adjust a setting of the feedback network based on the current operation mode.

7. The multi-mode power amplifying apparatus of claim 6 wherein the power amplifier includes a gain stage and an output stage, and the feedback network is coupled between an output and an input of the gain stage, the tuning controller configured to control one or more switching elements of the feedback network based on the current operation mode.

8. The multi-mode power amplifying apparatus of claim 1 further comprising an output matching network coupled to an output of the power amplifier and having a first section and a second section, the power amplifier, the attenuator, and the first section residing on a first semiconductor die, the second section residing on a second semiconductor die, the tuning controller configured to adjust a setting of the first section and a setting of the second section based on the current operation mode.

9. The multi-mode power amplifying apparatus of claim 8 wherein the tuning controller is configured to adjust the setting of the first section by controlling one or more switching elements of the first section and to adjust the setting of the second section by controlling one or more switching elements of the second section.

10. The multi-mode power amplifying apparatus of claim 1 wherein the power amplifier includes a gain stage and a first bias circuit configured to bias the gain stage, the tuning controller configured to, based on the current operation mode, adjust a setting of the first bias circuit to set a base ballast of the gain stage.

11. The multi-mode power amplifying apparatus of claim 10 wherein the power amplifier further includes an output stage coupled to an output of the gain stage, and a and a second bias circuit configured to bias the output stage, the tuning controller configured to, based on the current operation mode, adjust a setting of the second bias circuit to set a base ballast of the output stage.

12. A multi-mode power amplifying apparatus comprising:
a power amplifier including a first bias circuit configured to bias the power amplifier; and
a tuning controller, the multi-mode power amplifying apparatus adapted to operate in a plurality of operation modes and configured to amplify, in each operation mode of the plurality of operation modes, a radio frequency signal with an associated power amplifier gain, the tuning controller configured to, based on a current operation mode of the plurality of operation modes, adjust a reference current profile over temperature for the first bias circuit.

13. The multi-mode power amplifying apparatus of claim 1 further comprising an attenuator, the tuning controller configured to adjust a setting of the attenuator based on the current operation mode.

14. The multi-mode power amplifying apparatus of claim 13 wherein the setting of the attenuator is an attenuator profile over temperature.

15. The multi-mode power amplifying apparatus of claim 12 wherein the power amplifier further includes a gain stage, an output stage, and a second bias circuit configured to bias the output stage, the first bias circuit configured to bias the gain stage, the tuning controller configured to, based on the current operation mode, adjust a reference current profile over temperature for the second bias circuit.

16. The multi-mode power amplifying apparatus of claim 12 further comprising a feedback network coupled to an input of the power amplifier, the tuning controller configured to control one or more switching elements of the feedback network based on the current operation mode.

17. The multi-mode power amplifying apparatus of claim 12 further comprising an output matching network coupled to an output of the power amplifier and having a first section and a second section, the power amplifier, the first bias circuit, and the first section residing on a first semiconductor die, the second section residing on a second semiconductor die, the tuning controller configured to adjust a setting of the first section and a setting of the second section based on the current operation mode.

18. The multi-mode power amplifying apparatus of claim 17 wherein the tuning controller is configured to adjust the setting of the first section by controlling one or more switching elements of the first section and to adjust the setting of the second section by controlling one or more switching elements of the second section.

19. The multi-mode power amplifying apparatus of claim 12 wherein the tuning controller is configured to, based on the current operation mode, adjust a setting of the first bias circuit to set a base ballast of the power amplifier.

20. A method of operating a multi-mode power amplifying apparatus, the method comprising:
setting an attenuator of a power amplifying apparatus to a first state based on a first operation mode;
amplifying a radio frequency signal with the power amplifying apparatus in the first operation mode;
setting the attenuator of the power amplifying apparatus to a second state based on a second operation mode; and
amplifying the radio frequency signal with the power amplifying apparatus in the second operation mode;
